(19) United States
(12) Patent Application Publication
(10) Pub. No.: US 2025/0120022 A1
(43) Pub. Date: Apr. 10, 2025

(54) PORTABLE ELECTRONIC ITEM COMPRISING A SECURITY DEVICE FOR SECURING A COVER OF A REMOVABLE ELECTRICAL POWER SOURCE

(71) Applicant: ETA SA Manufacture Horlogère Suisse, Grenchen (CH)

(72) Inventor: David JOYE, Vauffelin (CH)

(73) Assignee: ETA SA Manufacture Horlogère Suisse, Grenchen (CH)

(21) Appl. No.: 18/886,440

(22) Filed: Sep. 16, 2024

(30) Foreign Application Priority Data
Oct. 6, 2023 (EP) 23202215.2

(51) Int. Cl. H05K 5/02; G04C 10/00; G04G 17/04; H05K 5/00; H05K 5/03

(52) U.S. Cl. CPC H05K 5/0208; G04C 10/00; G04G 17/04; H05K 5/0086; H05K 5/03

(57) ABSTRACT

A portable electronic item (100) including: a casing (10) having a compartment (11) for housing a removable electrical power source (2); a cover (20) including first coupling elements (23a) that cooperate with second coupling elements (23b) provided on the casing (10) to rigidly connect the cover (20) to the casing (10) by relative rotation. The cover (20) has an indentation (22) in an outer face (21) for receiving a tool for rotating the cover (20). A security device (30, 30′) is rigidly connected by adhesive bonding to the portable electronic item to at least partially cover the indentation (22) of the cover (20) of the compartment (11), so as to prevent the introduction of a tool for rotating the cover (20) and removing it from the casing (10).

### CROSS REFERENCE TO RELATED APPLICATIONS

This application is claiming priority based on European Patent Application No. 23202215.2 filed on Oct. 6, 2023.

### TECHNICAL FIELD OF THE INVENTION

The invention relates to portable electronic items powered by a removable electrical power source, such as a battery, accumulator or cell, housed in a compartment of a casing and closed by a cover.

The invention relates more particularly to a security device configured to secure a cover of a removable electrical power source and to prevent its removal, so as to prevent access to the electrical power source while the security device is in place.

The invention is of particular interest in the field of watchmaking and relates more particularly to an electronic or electromechanical watch.

### TECHNOLOGICAL BACKGROUND

Portable electronic items can be powered by one or more removable power sources, such as batteries, accumulators or cells.

For example, electronic or electromechanical watches are powered, at least in part in the case of electromechanical watches, by a removable electrical power source, for example a button cell, which is housed in a compartment in the watch case. A removable cover is provided to enclose the battery inside the compartment, while ensuring that the compartment is at least watertight.

To allow the battery to be easily replaced, the cover and the case typically have fast, rotational coupling/uncoupling means which allow quick access to the battery, as well as fast closure of the compartment after the battery has been replaced. These fast coupling/uncoupling means are, for example, quarter-turn type assembly systems or bayonet type assembly systems.

Moreover, the cover can have an indentation in its outer surface configured to receive the end of a tool to provide for the rotation thereof. To further facilitate battery replacement, it is common for this indentation to have a relatively simple and common shape, such as a slot, so that various accessories available to the wearer can be used to open the compartment without the need for a specific tool, or the need to take the watch to a watchmaker for battery replacement.

However, these various interesting and advantageous technical solutions for replacing the battery can also present drawbacks in certain situations, particularly when handled by children, especially young children. This is because young children could inadvertently remove the battery cover and gain access to the battery compartment, which could lead to the battery being swallowed and all of the serious consequences that could entail.

As a result, there is a need to secure this type of portable item to prevent an irresponsible person, particularly young children, from accessing the battery compartment, while retaining the advantages of the easy and quick removal of the cover without the need for a specific tool.

### SUMMARY OF THE INVENTION

To this end, the invention aims to propose a security device for securing a cover to a compartment for a removable electrical power source, such as a cell, accumulator or battery, of a portable electronic item, which device can be used to overcome at least one of the aforementioned drawbacks.

In this context, the invention relates to a portable electronic item including:
a casing having a compartment configured to receive and house at least one removable electrical power source;
a compartment cover including first coupling elements configured to cooperate with second coupling elements provided on the casing so as to rigidly connect the cover to the casing by rotating said cover about a rotational axis formed by a central axis of the cover; said cover having an indentation provided in an outer face, said indentation being configured to receive a tool for rotating the cover.

Moreover, the portable electronic item includes a security device rigidly connected by adhesive bonding to said portable electronic item, said security device being configured to at least partially cover the indentation of the compartment cover, so as to prevent the introduction of a tool for rotating the cover and removing it from the casing.

Thus, the bonded security device renders the indentation unusable as long as the security device is in place, by superimposing itself on top of the indentation so as to fill it and/or conceal it.

In addition to the features mentioned in the preceding paragraph, the portable electronic item according to the invention can have one or more complementary features from among the following, considered either on an individual basis or according to any combination technically possible:
the security device includes a main body having a flat surface, and anti-rotation lugs, the anti-rotation lugs being housed in notches formed in the casing, so as to prevent the cover from being rotated relative to the casing;
the anti-rotation lugs extend in a plane parallel to the plane of the flat surface of the main body, in a radial direction relative to the central axis X;
the anti-rotation lugs project from the flat surface of the main body and extend towards the compartment;
the security device is configured to completely cover the indentation in the cover;
the security device is rigidly connected to the cover by bonding;
the cover includes an outer face and the security device is rigidly connected to the outer face of the cover by bonding;
the item includes an adhesive element formed on an inner face of the main body to rigidly connect the security device to the outer face of the cover;
the security device is rigidly connected, at least in the indentation in the cover, by bonding;
the item includes an adhesive element formed on an inner face of the main body to rigidly connect the security device at least inside the indentation in the cover;
the security device is rigidly connected to the casing by bonding;
each of the anti-rotation lugs are rigidly connected at the bottom of a notch in the casing by bonding by means of an adhesive element;
the adhesive element is an adhesive film or glue;
the main body has a cut-out allowing a small tool to pass into the indentation to facilitate the detachment of the security device from the portable electronic item;
the security device is made of a metal or polymer material;
the portable electronic item is a timepiece.

### BRIEF DESCRIPTION OF THE FIGURES

The purposes, advantages and features of the present invention will be better understood upon reading the detailed description given below with reference to the following figures:

FIG. 1 is a view illustrating the back or rear of a portable electronic item according to the invention including a first example embodiment of a security device for securing a cover of a removable electrical power source, such as a cell, accumulator or battery;

FIG. 2 is a semi-exploded, perspective view of the portable electronic item illustrated in FIG. 1;

FIG. 3 shows how the security device is fitted to the portable electronic item shown in FIG. 1, when the compartment is closed by the cover;

FIG. 4 is a view illustrating the back or rear of a portable electronic item according to the invention including a second example embodiment of a security device for securing a cover;

FIG. 5 illustrates more precisely the second example embodiment of the security device illustrated in FIG. 4; FIG. 5 shows more precisely a bottom view illustrating the face intended to face the cover;

FIG. 6 illustrates another example embodiment of a cover with a differently shaped indentation;

FIG. 7 illustrates a third example embodiment of a security device according to the invention, which security device is configured to fit into the indentation in the cover illustrated in FIG. 6;

FIG. 8 illustrates a fourth example embodiment of a security device according to the invention, which security device is configured to fit into the indentation in the cover illustrated in FIG. 6.

In all the figures, common elements bear the same reference numerals unless specified to the contrary.

### DETAILED DESCRIPTION OF THE INVENTION

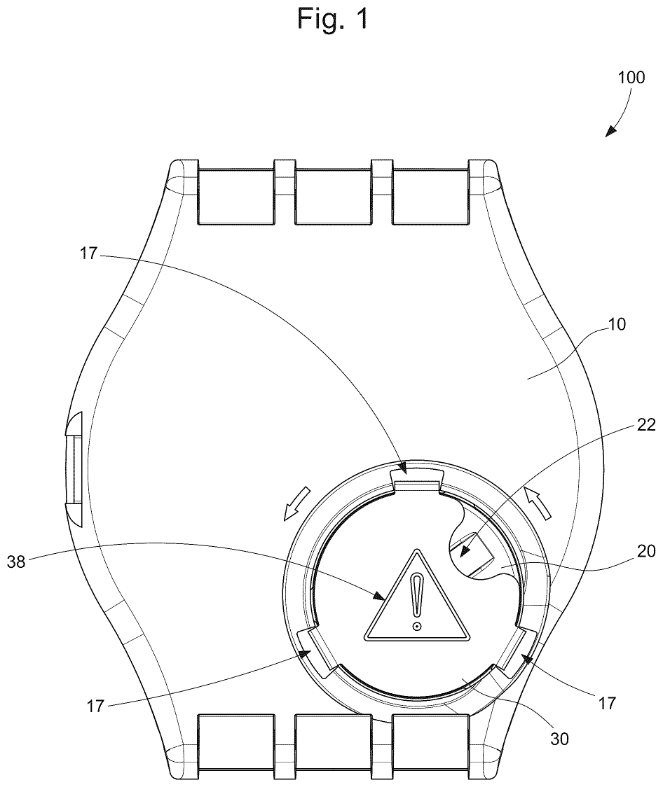

FIG. 1 is a view illustrating the back or rear of a casing of a portable electronic item 100 according to the invention including a first example embodiment of a security device for securing a cover of a removable electrical power source, such as a cell, accumulator or battery.

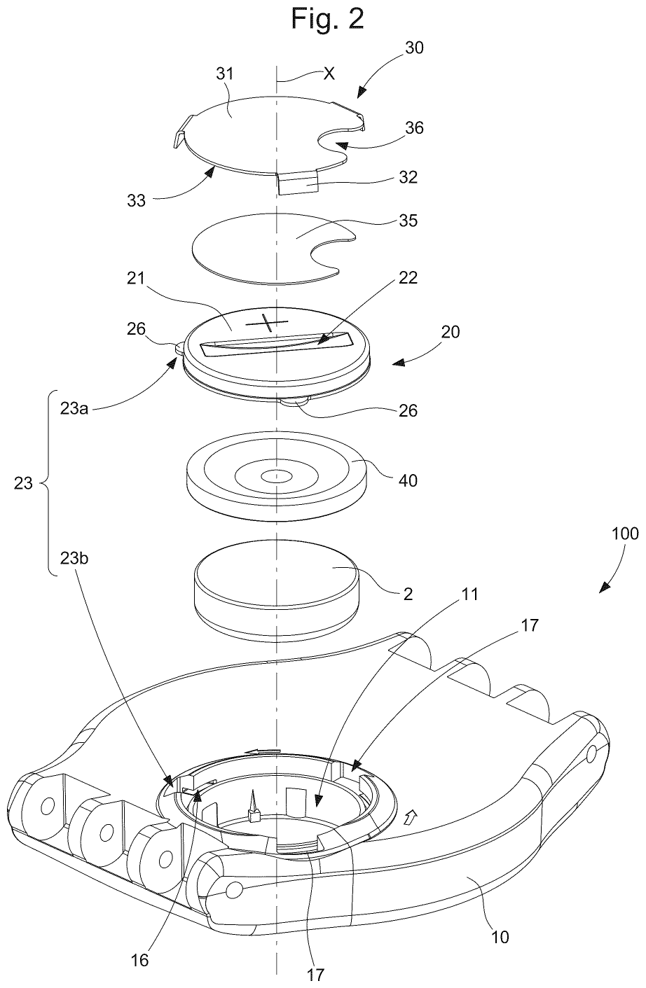

FIG. 2 is a semi-exploded, perspective view of the portable electronic item 100 shown in FIG. 1.

The portable electronic item 100 is, for example, a timepiece, such as a watch. However, other example embodiments are possible.

The portable electronic item 100 includes a casing 10 (or a watch case when the item is a watch) enclosing an electronic unit (not shown) powered by at least one removable power source, for example in the form of a cell, an accumulator or a battery.

As can be seen in FIG. 2, the casing 10 has a compartment 11 configured to receive and house at least one removable electrical power source 2.

Typically, on a watch, the compartment 11 is located at the back of the watch, i.e. at a part of the watch intended to come into contact with the user's skin.

Depending on the electrical power required by the portable electronic item, the compartment 11 can be sized to receive and house a plurality of removable electrical power sources, for example a plurality of cells, accumulators or batteries.

In the remainder of this application, the removable electrical power source 2 will be considered to be a cell battery.

The cell battery 2 housed in the compartment 11 is a button cell for example.

The compartment 11 of the casing 10 forms a recess that is, for example, cylindrical in shape, extending substantially along a central axis X.

The compartment 11 of the casing 10 is closed by a cover 20 with a central axis X. The compartment 11 is closed by rotating the cover 20 about the central axis X.

The cover 20 includes first coupling elements 23a configured to cooperate with second coupling elements 23b provided on the casing 10. The coupling elements 23a, 23b are configured to rigidly connect the cover 20 to the casing 10 by rotating said cover about the central axis X. The first coupling elements 23a and the second coupling elements 23b thus form a system 23 for attaching the cover 20 to the casing 10.

Preferably, the coupling elements 23a, 23b of the attachment system 23 are fast, rotational coupling system, allowing the compartment 11 to be opened quickly and easily.

Preferably, the coupling elements 23a, 23b are, for example, devices allowing quarter-turn coupling or bayonet coupling.

For example, the cover 20 has tabs 26 extending radially relative to the central axis X. The tabs 26 are configured to cooperate and fit into grooves 16 formed in the casing 10 around the periphery of the compartment 11. Thus, the tabs 26 of the cover 20 form the first coupling elements 23a and the grooves 16 in the casing 10 form the second coupling means 23b.

According to one alternative embodiment, the coupling elements 23a, 23b are screw coupling devices, so that the cover 20 is rigidly connected to the casing 10 by screwing.

The cover 20 has an indentation 22 made in an outer face 21, i.e. the face of the cover 20 visible to the user when the cover 20 is coupled to the casing 10.

The indentation 22 is formed by a surface set back from the outer face 21. The indentation 22 is shaped to receive the end of a tool and ensure rotation of the cover 20 when a rotation torque is exerted on the cover 20 using the tool.

Preferably, the indentation 22 has a simple shape. For example, the indentation 22 has the shape of a groove, a straight notch or a slot.

The indentation 22 can also have other, more complex shapes.

FIG. 6 illustrates another example embodiment of an indentation 122 made in the shape of a straight groove. In this example embodiment, the indentation 122 communicates with a circumferential groove 123 running around the outer face 21 of the cover 120.

The casing 10 further includes notches 17 extending substantially along the axis X and into which the grooves 16 open out. The casing 10 includes as many notches 17 as there are tabs 26 on the cover 20.

The notches 17 are configured to receive tabs 26 of the cover 20 for coupling of the cover 20, by the rotation thereof, thus engaging the tabs 26 in the grooves 16. When the tabs 26 are at the bottom of the grooves 16, the cover 20 is coupled to the casing 10 and the compartment 11 is closed.

The grooves 16 can be raised or embossed to indicate the passage of a certain angular position and provide a sensory indication that the cover 20 has been closed correctly.

As shown in FIG. 2, a resilient membrane 40 is inserted between the cell battery 2 and the cover 20 to seal the compartment 11.

The portable electronic item 100 further includes a security device 30 bonded to the portable electronic item 100.

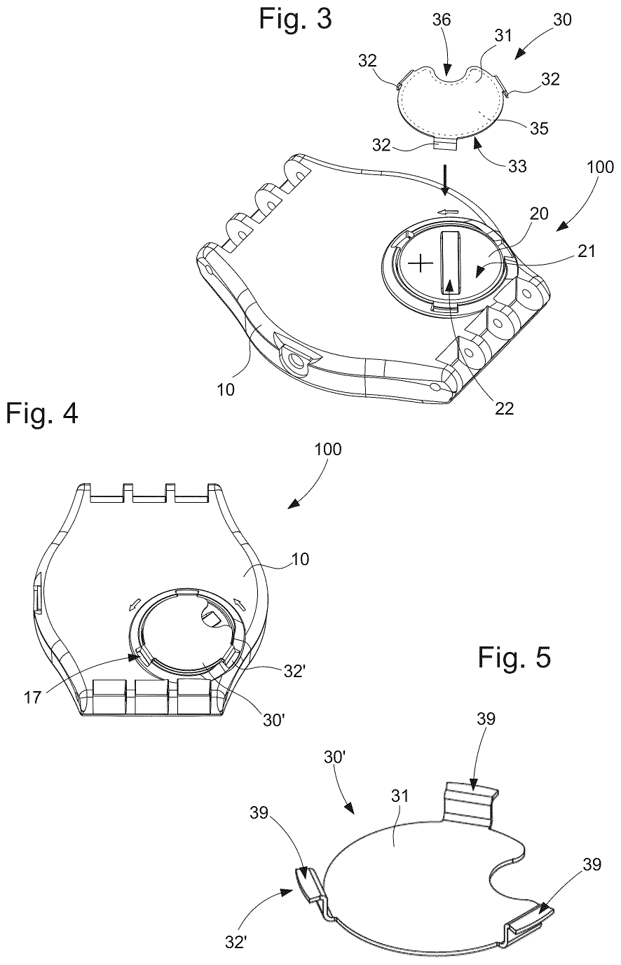

The security device 30 is an attachment rigidly connected to the portable electronic item 100 by bonding once the cover 20 is coupled to the casing 10, and closes the compartment 11, as shown in FIG. 3. FIG. 3 shows the cover 20 in the closed position on the casing 10 and the tabs 26 of the cover 20 in the grooves 16.

The security device 30 includes a main body 31 forming a flat surface and anti-rotation lugs 32.

In the example embodiment shown in FIGS. 1 to 3, the anti-rotation lugs 32 project from the flat surface of the main body 31.

The main body 31 is sufficiently rigid to not deform under its own weight when held by one end. Thus, the security device 30 is a “rigid” part which differs from a flexible label.

The anti-rotation lugs 32 are lugs which extend in relief relative to the flat surface of the main body 31. They thus form an angle of between approximately 45° and 120° relative to the plane formed by the flat surface of the main body 31, and are directed towards the casing 10.

The anti-rotation lugs 32 are configured to fit into and cooperate with notches in the casing 10 so as to prevent any rotation of the security device 30 about the axis X. Thus, when the security device 30 is rigidly connected to the portable electronic item 100 by bonding and covers the cover 20, it is no longer possible to rotate the cover 20 and remove it.

Preferably, the notches 17 used for mounting the cover 20 and which are free, when the cover 20 is in the closed position, are used to house the anti-rotation lugs of the security device 30.

However, if required, specific notches can also be made in the casing 10 to receive the anti-rotation lugs 32 of the security device 30.

The main body 31 of the security device 30 is configured to at least partially cover the cover 20 and its indentation 22, i.e. the recessed surface forming the indentation 22, and preferably a large part of the cover 20 and of the indentation 22.

Thus, the security device 30 renders the indentation 22 unusable for as long as the security device 30 is in place, by superimposing itself on top of the indentation 22.

The main body 31 is dimensioned to sufficiently cover the indentation 22 in the cover 20 so that it is no longer possible to engage a tool in the indentation 22 and thus rotate the cover 20 using the tool in the indentation 22.

The main body 31, for example, has the shape of a disc or patch, the diameter of which is substantially equivalent to the diameter of the cover 20.

The main body 31 can have a cut-out 36, a break in shape, an opening or a slot configured to allow a tool of small dimensions to reach the indentation 22 of the cover 20 over a limited portion. Thus, it is possible to use a tool of smaller dimensions than that required to rotate the cover 20 via the indentation 22, to make it easier to remove and detach the security device 30 from the cover 20, particularly when the compartment 11 must be opened in order to replace the cell battery 2. However, this cut-out 36 is not sufficient to rotate the cover using the indentation 22 and a tool adapted to the indentation 22.

The security device 30 is rigidly connected to the portable electronic item 100 by bonding, for example by means of an adhesive element 35.

In this first example embodiment illustrated in FIGS. 1 to 3, the security device 20 is rigidly connected to the cover 20 by bonding using an adhesive element 35.

In this first example embodiment, the adhesive element 35 is provided on the inner face 33 of the main body 31 of the security device 30 in order to rigidly connect the security device 30 to the outer face 21 of the cover 20 by bonding.

Thus, the adhesive element 35 forms a bonding interface between the inner face 33 of the main body 31 and the outer face 21 of the cover 20.

It goes without saying that, typically speaking in the present application, the outer face is the face directed towards the exterior of the portable electronic item and, conversely, the inner face is the face directed towards the interior of the portable electronic item.

The adhesive element 35 is, for example, an adhesive film, for example of the double-sided type, a glue, or another equivalent element.

When the adhesive element 35 is an adhesive film, the adhesive film can have a shape substantially equivalent to the shape of the main body 31, if necessary with a shape to follow the cut-out 36 in the main body 31.

The adhesive film or, more generally, the adhesive element 35, can also have smaller dimensions than the main body 31 of the security device 30.

Preferably, the adhesive element 35 is resistant to a temperature of at least 90° C.

As can be seen in FIG. 1, when the security device 30 is bonded to the cover 20, the anti-rotation lugs 32 are housed in the notches 17 so that they prevent rotation of the cover 20.

To detach the security device 30 during a battery change, the user can easily use a small tool and insert it under the main body 31 at the cut-out 36 in the main body 31, advantageously making use of the removal of material from the indentation 22 in the cover 20. Once the security device 30 has been detached, the user has access to the indentation 22 in the cover 20, allowing the user to rotate same and access the cell battery 2 housed in the compartment 11.

In a second example embodiment shown in FIGS. 4 to 5, the security device 30′ is rigidly connected to the casing 10 by bonding by means of the anti-rotation lugs 32′.

To this end, as shown in FIG. 5, the anti-rotation lugs 32′ have an S shape delimiting a bearing surface 39 configured to rest against the bottom of a notch 17. The bearing surface 39 is sufficiently wide and flat to cooperate with the bottom of the notches 17 and to receive an adhesive interface element 35 for rigidly connecting the security device 30′ in the notches 17 of the casing 10 by bonding.

Preferably, the bearing surface 39 of the anti-rotation lugs 32′ is substantially parallel to the flat surface of the main body 31.

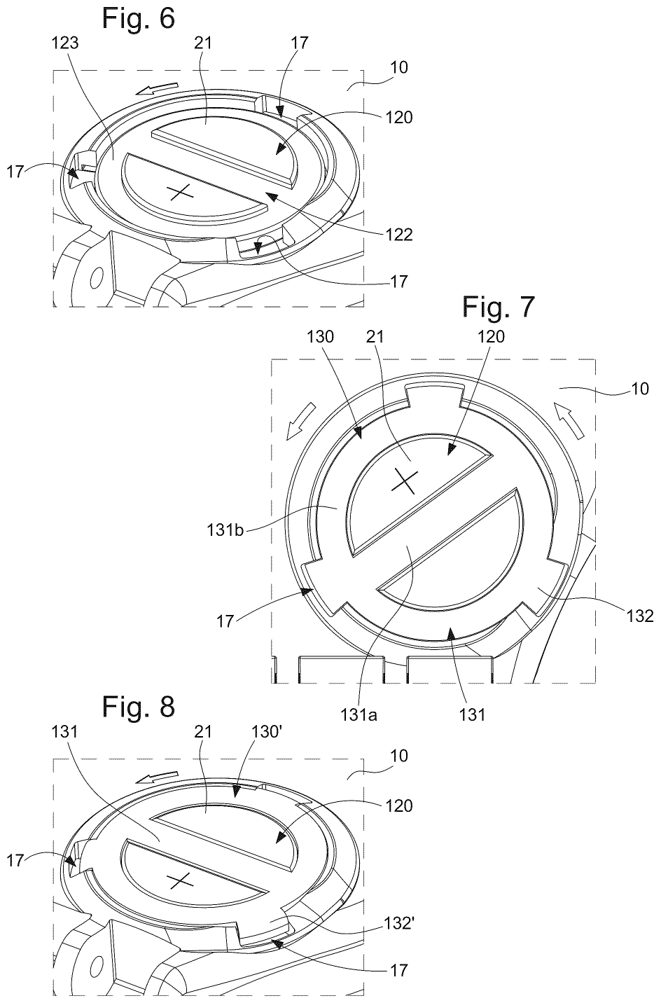

FIG. 7 illustrates a third example embodiment of a security device 130 for a battery or cell cover 120.

This third example embodiment is configured to cooperate with the shape of the cover 120 shown in FIG. 6, the outer face 21 of which has an indentation 122 in the form of a straight groove communicating with a circumferential groove 123 running around the outer face 21 of the cover 120.

In this third example embodiment, the security device 130 includes a body 131 having a flat surface configured to fit into the indentation 122, so as to at least partially fill the indentation 122 and cover the indentation 122, or more precisely to cover the recessed surface forming the indentation 122.

Thus, in this third example embodiment, the body 131 has a central portion 131a and a peripheral portion 131b configured to fit respectively into the indentation 122 and into the circumferential groove 123 in the cover 120. The body 131 thus has the shape of a circle with a line through it, representing the no symbol which covers the indentation 122.

Preferably, the thickness of the body 131 is substantially equal to the depth of the indentation 122.

The security device 130 is bonded via an adhesive element 35 produced on the inner face of the body 131.

The security device 130 is bonded at least in the indentation 122, preferably in the indentation 122 and in the circumferential groove 123 in the cover 120.

In this third example embodiment, the security device 130 includes anti-rotation lugs 132 extending radially relative to the central axis X and which extend in the same plane or in a plane parallel to the plane of the flat surface of the body 131.

In the same way as the example embodiments described above, the anti-rotation lugs 132 are configured to be housed in the notches 17 in the casing 10. Thus, it is no longer possible to rotate the cover 120 as long as the security device 130 is rigidly connected to the cover by bonding.

FIG. 8 illustrates a fourth example embodiment which is an alternative embodiment of the third example embodiment described above with reference to FIG. 7. In this fourth example embodiment, the security device 130′ includes anti-rotation lugs 132′ projecting from the flat surface of the main body 131′ and extending towards the compartment 11 to be housed deeper inside the notches 17 in the casing 10. Thus, it is no longer possible to rotate the cover 120 as long as the security device 130′ is in place on the cover.

In a fifth simplified example embodiment, the security device does not include anti-rotation lugs. In this fifth example embodiment, the main body 31, 131 is rigidly connected to the cover by bonding so as to cover the indentation 22, 122 as described above with reference to FIGS. 1 to 3 and 6 to 8.

In this fifth example embodiment, the main body 31 can be disc-shaped or pellet-shaped, with a diameter substantially equivalent to the diameter of the cover.

In this fifth example embodiment, the main body 31 can also have a shape as described with reference to FIGS. 7 and 8.

Regardless of which example embodiment is applied, the security device 30, 30′, 130, 130′ is made of a metal or polymer material.

As shown in FIG. 1, the security device 30, 30′ can also include a security, danger or prevention pictogram 38 visible on the outer face of the security device 30, 30′.

1. A portable electronic item comprising:
a casing having a compartment configured to receive and house at least one removable electrical power source;
a compartment cover including first coupling elements configured to cooperate with second coupling elements provided on the casing so as to rigidly connect the cover to the casing by rotating said cover about a rotational axis formed by a central axis of the cover; said cover having an indentation provided in an outer face, said indentation being configured to receive a tool for rotating the cover; and
a security device rigidly connected by adhesive bonding to said portable electronic item, said security device being configured to at least partially cover the indentation of the cover of the compartment, so as to prevent the introduction of a tool for rotating the cover and removing it from the casing.

2. The portable electronic item (100) according to claim 1, wherein the security device includes:
a main body having a flat surface, and
anti-rotation lugs,
the anti-rotation lugs being housed in notches made in the casing, so as to prevent rotation of the cover relative to the casing.

3. The portable electronic item according to claim 2, wherein said anti-rotation lugs extend in a plane parallel to the plane of the flat surface of the main body, in a radial direction relative to the central axis.

4. The portable electronic item according to claim 2, wherein said anti-rotation lugs project from the flat surface of the main body and extend towards the compartment.

5. The portable electronic item according to claim 1, wherein said security device is configured to completely cover the indentation in the cover.

6. The portable electronic item according to claim 1, wherein said security device is rigidly connected to the cover by bonding.

7. The portable electronic item according to claim 6, wherein said cover includes an outer face and in that the security device is rigidly connected to the outer face of the cover by bonding.

8. The portable electronic item according to claim 7, wherein said portable electronic item includes an adhesive element formed on an inner face of the main body to rigidly connect the security device to the outer face of the cover.

9. The portable electronic item according to claim 6, wherein said security device is rigidly connected, at least in the indentation in the cover, by bonding.

10. The portable electronic item according to claim 9, wherein said portable electronic item incudes an adhesive element formed on an inner face of the main body to rigidly connect the security device at least inside the indentation in the cover.

11. The portable electronic item according to claim 2, wherein said security device is rigidly connected to the casing by bonding.

12. The portable electronic item according to claim 11, wherein each of the anti-rotation lugs are rigidly connected at the bottom of a notch in the casing by bonding by means of an adhesive element.

13. The portable electronic item according to claim 1, wherein said security device is rigidly connected by adhesive bonding to said portable electronic item by an adhesive film or glue.

14. The portable electronic item according to claim 1, wherein said main body has a cut-out allowing a small tool to pass into the indentation to facilitate the detachment of the security device from the portable electronic item.

15. The portable electronic item according to claim 1, wherein said security device is made of a metal or polymer material.

16. The portable electronic item according to claim 1, wherein the portable electronic item is a timepiece.
